(19) United States
(12) Patent Application Publication
(10) Pub. No.: US 2011/0298490 A1
(43) Pub. Date: Dec. 8, 2011

(54) ASYMMETRICAL AGING CONTROL SYSTEM

(76) Inventors: ALAN SCOTT HEARN, Allen, TX (US); Gustavo Alberto Palau, Allen, TX (US); Calvin L. Clark, Coppell, TX (US)

(21) Appl. No.: 12/796,380

(22) Filed: Jun. 8, 2010

(51) Int. Cl. H03K 19/003

(52) U.S. Cl. 326/9

(57) ABSTRACT

An asymmetrical aging control system is described. This system actively varies associated dedicated circuits in a manner that minimizes power consumption, while preventing asymmetrical aging.

### DESCRIPTION OF RELATED ART

With the evolution of electronic devices, there is a continual demand for enhanced speed, capacity and efficiency in various areas including electronics. With this quest for efficiency, there may be a corresponding concern for reducing power consumption. Consequently, there remain unmet needs relating to power reduction solutions that reduce asymmetrical aging.

### BRIEF DESCRIPTION OF THE DRAWINGS

The asymmetrical aging control system may be better understood with reference to the following figures. The components within the figures are not necessarily to scale, emphasis instead being placed upon clearly illustrating the principles of the asymmetrical aging control system. Moreover, in the figures, like reference numerals designate corresponding parts or blocks throughout the different views.

FIG. 1A is an illustrative environmental drawing illustrating a router that includes an asymmetrical aging control system (AACS) in a master control within an application specific integrated circuit (ASIC).

FIG. 1B is a block diagram illustrating one implementation of components within the ASIC of FIG. 1A.

FIG. 2 is a block diagram illustrating components within one of the dedicated circuits of FIG. 1B.

FIG. 3A is a block diagram illustrating one implementation of a dedicated circuit associated with the AACS.

FIG. 3B is a table that indicates how the control logic block of FIG. 3A selects a particular mode.

FIG. 3C is a block diagram illustrating a second implementation of the dedicated circuit associated with the AACS.

FIG. 4 is a flow chart illustrating steps of one implementation for controlling asymmetric aging.

While the asymmetric aging control system is susceptible to various modifications and alternative forms, specific embodiments have been shown by way of example in the drawings and subsequently are described in detail. It should be understood, however, that the description herein of specific embodiments is not intended to limit the asymmetric aging control system to the particular forms disclosed. In contrast, the intention is to cover all modifications, equivalents, and alternatives falling within the spirit and scope of the asymmetric aging control system as defined by this document.

### DETAILED DESCRIPTION OF EMBODIMENTS

As used in the specification and the appended claim(s), the singular forms “a,” “an” and “the” include plural referents unless the context clearly dictates otherwise. Similarly, “optional” or “optionally” means that the subsequently described event or circumstance may or may not occur, and that the description includes instances where the event or circumstance occurs and instances where it does not.

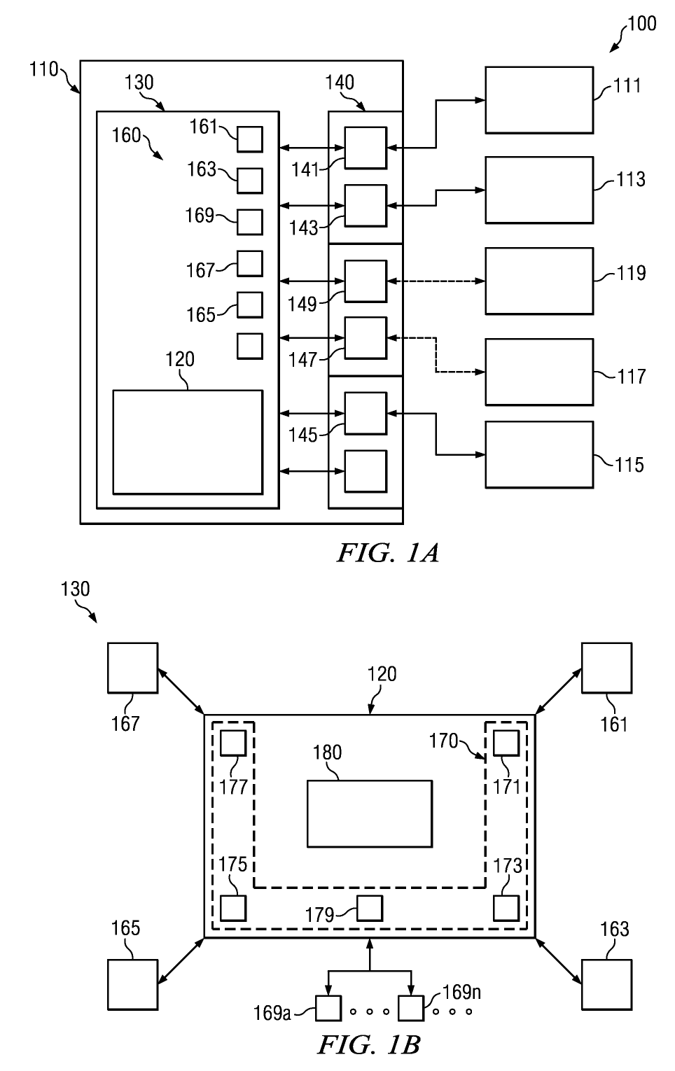

FIG. 1A is an illustrative environmental drawing 100 illustrating a router 110 that includes an asymmetrical aging control system (AACS) 120. The router 110 may exchange data with various other devices, such as the computer system 111, printer 115, or the computer system 113. More specifically, the router 110 may include an application specific integrated circuit (ASIC) 130 that facilitates communication with these devices using elements 140. For the router 110, these elements may be ports, such as port cards 141-149. Any numbers described in this document are for illustrative purposes only, since numerous alternative implementations may result by varying numbers without departing from the innovativeness of the AACS 120. The router 110 may also include a dedicated circuit group 160 (sub-chips) that controls the group of elements 140. For example, the dedicated circuit 161 may control the element 141, while the dedicated circuit 167 controls the element 147. While this implementation shows a one to one correlation between the number of elements and the number of dedicated circuits, an alternative implementation may have a two to one, three to one, or some other suitable correlation.

At some point, the ASIC 130 may need to exchange data with devices that previously were not connected, such as computer system 117 or device 119. To minimize power, the dedicated circuits 167-169 may have been in a low power state, such as an inactive state, because the elements 147-149 were empty. While in this low power state, the AACS 120 actively varies these dedicated circuits in a manner that minimizes power consumption, while preventing asymmetrical aging. When the computer system 117 connects to the element 147, a control signal disables the AACS 120 asymmetrical aging control of the dedicated circuit 167 and subsequently enables the dedicated circuit 167 communication with element 147. In response, the AACS 120 stops actively varying the dedicated circuit 167, while still actively varying the element 169. Thus, the AACS 120 may only minimize power consumption, while preventing asymmetrical aging for dedicated circuits in a low power state.

The environmental drawing is only one of many possible environments where the AACS 120 may be used. For example, numerous alternative implementations may result from adding more than one ASIC or having the ASIC 130 exchange data between more than one group of elements. In an alternative implementation, the AACS 120 may be included within another type of device, such as a security system, server, or the like. For that implementation, the elements 140 may be expansion slots for additional security feeds or increased server capacity respectively; the device 117 may be a video camera or a hard disk drive. In short, the AACS 120 may be used in any environment where there are unutilized components that may be used at some time in the future.

FIG. 1B is a block diagram illustrating one implementation of components within the AACS 120. This AACS includes a selection device group 170 and a generator 180 that collaboratively keep the dedicated circuits group 160 of FIG. 1A active to limit asymmetrical aging. For this selection group, there is one selection device for each dedicated circuit. For example, the selection device 171 associates with the dedicated circuit 161, while the selection device 175 associates with the dedicated circuit 165. For an alternative implementation, there may be fewer devices in the selection device group 170 than there are circuits in the dedicated circuits group 160. For example, the selection device 179 may associate with two or more dedicated circuits 169a-169n. The generator 180 may include one or more elements that may transmit a clock signal or a data signal and a clock signal. The selection device group 170 may control all of the dedicated circuits in the group 169a-169n.

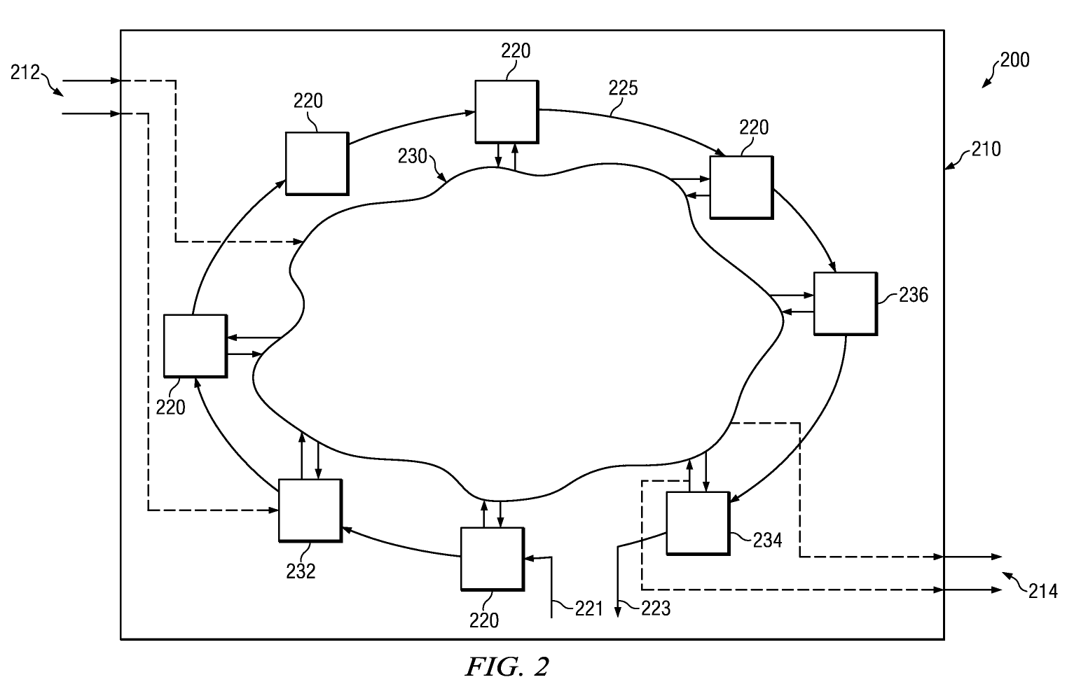

FIG. 2 is a block diagram 200 illustrating scan elements within a scan path for the dedicated circuit 210 that is controlled by the AACS 120. These scan elements are interconnected in a ring that is sourced from the AACS 120 via scan input 221. The output 223 of this scan ring is not used in conjunction with AACS, but is necessary for normal test. For each scan ring of a dedicated circuit 210, the scan input 221 can be sourced from a generator (e.g., generator 180), and a selection device (e.g., selection device 175). As illustrated, the dedicated circuit 210 may receive data as input signals 212 and transmit output signals 214. For example, the dedicated circuit 210 may receive a signal from either an associated element or from another dedicated circuit as input signals 212. Similarly, the dedicated circuit 210 may transmit output signals to either an associated element or to the master control 110. In other words, this dedicated circuit may become a conduit for transmitting data between a device in the element group 140 and another circuit, such as another dedicated circuit.

The dedicated circuit 210 may include numerous devices 220 that use a scan path, or scan ring, 225. For example, the devices 220 may be data flip-flops that may utilize a scan path arrangement for serially passing data from one flip-flop to the next. While the scan path 225 is shown with logic devices 220 that make the ring, the dedicated circuit also includes a cloud 230. This cloud is a pictorial representation of various logic devices that may either receive from or transmit data to one of the logic devices 220 within the scan path. As illustrated, this cloud of logic devices may receive the input signal 212 directly or the input signal may be sent to a device 232 on the scan path 225. Also, the cloud 230 may directly receive data from or transmit data to one of the devices 220 on this scan path. Similarly, the output signals 214 may come directly from the cloud 230. Alternatively, the output signal may come directly from either device 234 or device 236. In another implementation, the cloud may also receive the output signal from the device 234. Moreover, these are merely a few of the many possible implementations of the dedicated circuit 210.

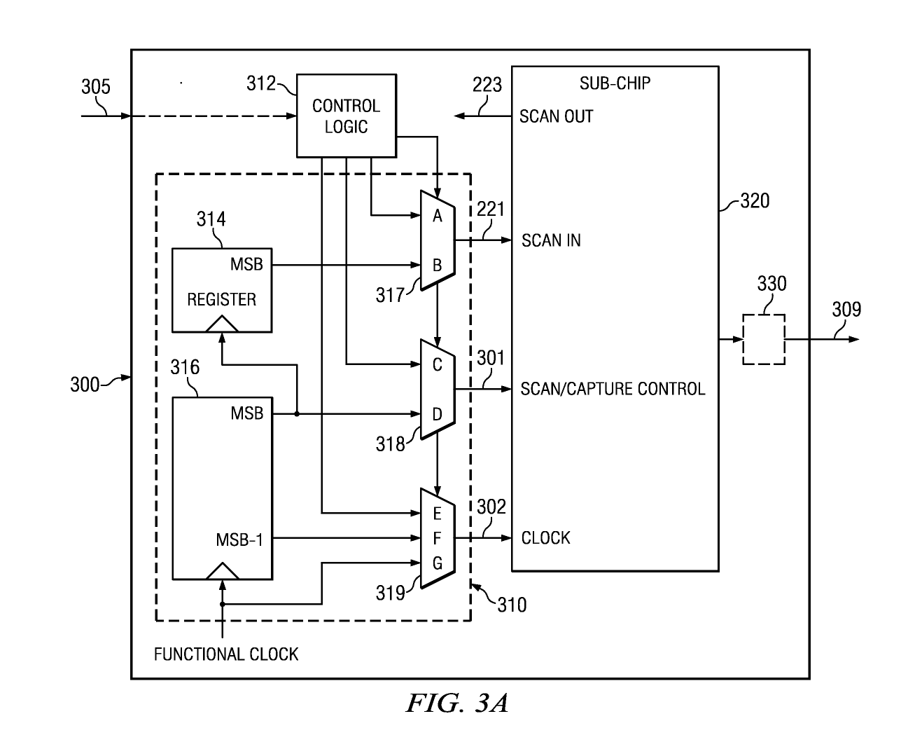

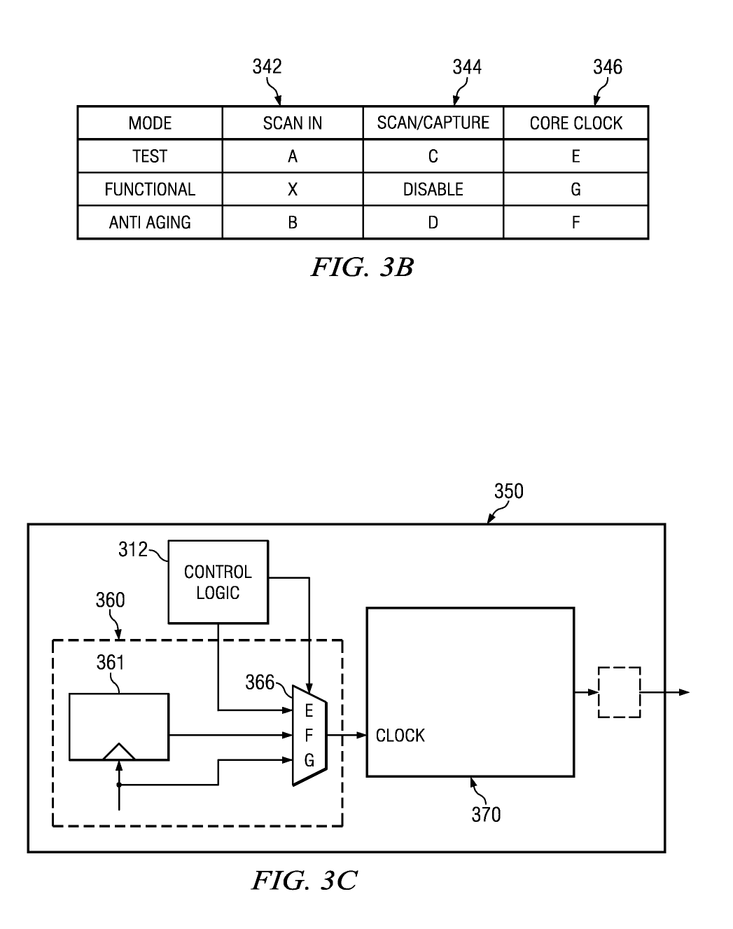

FIG. 3A is a block diagram 300 illustrating one implementation of the AASC 120 that may receive a control signal on connection 305. The asymmetric control logic 310 is one implementation of the AACS 120. The control signal 305 enters a control logic block 312, which may select between various modes.

The asymmetric control logic 310 also includes a register 314 and a counter 316 that receives a functional clock; this register and counter are elements within the generator 180 described with reference to FIG. 1B. This register may be one of many types of registers, such as a linear feedback shift register that is used to produce random data for input to the scan in port 221 of dedicated circuit 320. Selection devices, or multiplexers 317-319, receive signals from the control logic 312, register 314, and counter 316. These devices select which of the signals on their input get passed to the dedicated circuit 320.

Finally, the block diagram 300 can also include an output device 330 that prevents the output signal 309 from changing state when AACS is enabled. As a result, dedicated circuit 320 appears inactive to other circuits. Note that output signal 309 may be a single output or a multitude of outputs that need to be placed into an inactive state. This output device controls when the output signal 309 leaves this dedicated circuit. The output device 330 may be a single logic gate, combination of logic gates, or a state machine. For example, this output device may be an AND gate in one implementation.

The operation of the block diagram 300 may vary depending on whether it is either active or inactive. The register 314 may be a scan register that transmits a pseudo-random pattern to the selection device 317. In contrast, the control logic 312 may transmit scan data and an enable to this same selection device. By receiving a functional clock, the counter 316 may transmit a first count signal that the selection device 318 receives and a second count signal that the selection device 319 receives. The first count signal may differ from the second count signal by one, two, or the like. For example, the count signal to the selection device 319 may toggle at twice the rate of the count signal to 318. In the implementation illustrated in FIG. 3A, the selection device 317 couples to a scan input 221 for the dedicated circuit 320. In contrast, the selection device 318 couples to a scan/capture control input, while the selection device 319 couples to the clock input 302. The selection devices 318-319 also receive an enable signal from control logic 312.

Using the asymmetric aging control logic 310, it injects pseudo-random data for each scan cycle and then evaluates the data from the previous scan cycle during the capture cycle. More specifically, the counter 316 may transmit the first count signal to the selection device 318 using the most significant bit, or MSB. Using the MSB to clock the register 314 also allows generation of new random data for each scan cycle. When the selection device 318 receives this first count signal, this selection device may enable a scan mode, such that the selection device 317 transmits the pseudo-random data received from the register 314. At some point later, the first count signal may change state such that the selection device 318 may enable a capture mode. In this mode, the previously scanned data propagates through the sub-chip 320. To facilitate the switching between a scan mode and a capture mode, the counter 316 transmits a second count signal to the selection device 319 using the MSB-1, which has a frequency of approximately twice the frequency of the signal sent to the MSB. Consequently, the asymmetrical aging control 310 toggles both a scan path associated with the scan mode and a functional path associated with the capture mode. The selection device 319 toggles the clock input of the dedicated circuit 320 by using the second count signal and the functional clock. This toggling may be done at one of many frequencies, such as approximately 1 Hz, 1.5 Hz, 2 Hz, or some other suitable frequency.

FIG. 3B is a table that indicates how the control logic block 312 selects a particular mode. As illustrated, the control logic block 312 may select a test mode, functional mode, or anti-aging mode. For selection device 317, column 342 illustrates which input is applied to the output 221. Similarly, column 344 and column 346 illustrate selected inputs for the selection devices 318 and 319, respectively.

FIG. 3C is a block diagram illustrating a second implementation of the AACS 120 and is shown as asymmetric aging control system 360, which includes a counter 361. This counter functions substantially similar to the counter 316. In operation, asymmetric aging control system 360 does not inject random data into the scan path, but does minimize asymmetric aging, by toggling a clock input to the dedicated circuit 370. In operation, asymmetric aging control 360 differs from asymmetric aging control 310 in that there is no injection of random data into the design. In this method, data path aging would be accounted for by other means, such as additional margining.

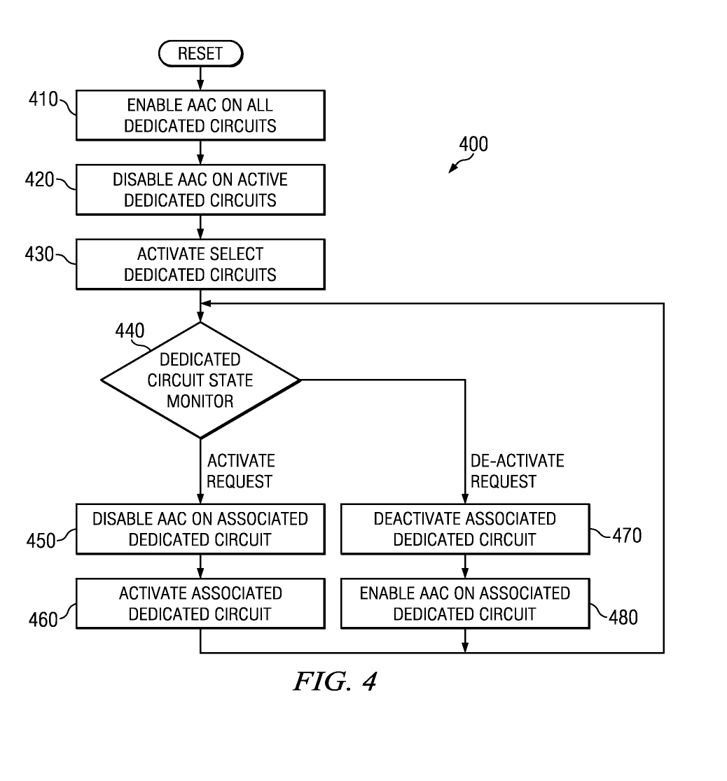

FIG. 4 is a flow chart 100 illustrating steps of one implementation for controlling asymmetric aging. This may be implemented within software as an ordered listing of executable instructions for implementing logical functions that can be embodied in any computer-readable medium within the master control 110 (see FIG. 1B). This medium may be for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer-readable medium can be, for example, but, not limited to, an electronic, magnetic, optical, electromagnetic, infrared, or semiconductor system, apparatus, device, or propagation medium. More specific examples (a non-exhaustive list) of the computer-readable medium can include the following: an electrical connection (electronic) having one or more wires, a portable computer diskette (magnetic), a random access memory (RAM), a read-only memory (ROM), an erasable programmable read-only memory (EPROM or Flash memory) (magnetic), an optical fiber (optical), and a portable compact disc read-only memory (CDROM) (optical). Note that the computer-readable medium can even be paper or another suitable medium upon which the program is printed. The program can be electronically captured, via for instance optical scanning of the paper or other medium, then compiled, interpreted or otherwise processed in a suitable manner if necessary, and then stored in a computer memory.

In block 410, asymmetric aging control (AAC) may be enabled on all dedicated circuits associated with the element group 140. Elements may be any kind of sub-system, such as port logic or any low frequency use function where the circuit is off for an extended period of time. This enabling may be done during an initialization mode. Block 410 is followed by block 420. In this block, the AAC is disabled for all active dedicated circuits. In other words, active dedicated circuits are dedicated circuits that will be currently utilized. This block may include additional blocks used in assessing the state of all dedicated circuits and categorizing them as dedicated circuits to be activated or dedicated circuits to be inactivated. For example, dedicated circuits to be inactivated may include dedicated circuits that may be for adding capacity at some point in the future, but may not be desired at this point.

Block 430 follows block 420. In block 430, all associated dedicated circuits may be activated. This activation may be done by performing whatever tasks necessary to enable to the dedicated circuits to execute under normal operating conditions, which may vary from system to system. In block 440, all the dedicated circuit's states are monitored. This monitoring may be done programmatically, mechanically, or by some other suitable technique. For a programmatic solution, this monitoring may involve periodically sending a test signal and assessing whether the resulting signal is either inside or outside of a given threshold. Alternatively, this monitoring may be done mechanically by applying a predetermined voltage and waiting until the addition of a dedicated circuit causes a state change or variation from the threshold. In addition, this block may determine whether a dedicated circuit should be inactivated or if the AAC should be inactivated. This determination may involve analyzing either a dedicated circuit's possible functionality relative to overall system needs or additional capacity, such as bandwidth or storage.

If a dedicated circuit should be activated, block 450 receives a dedicated circuit activate request. In response to receiving this request, block 450 disables the AAC on the associated dedicated circuit. This process may involve identifying the dedicated circuit mentioned in the request, identifying the AAC associated with dedicated circuit, and transmitting a disable for AAC via associated signal 305 for example. In block 460, the associated dedicated circuit is activated. This may involve fully powering the associated dedicated circuit.

If a dedicated circuit should be de-activated, block 470 receives a dedicated circuit de-activate request. In response to receiving this request, block 470 deactivates the associated dedicated circuit via associated signal 305 for example. This process may involve identifying the dedicated circuit mentioned in the request, identifying the AAC associated with the dedicated circuit and transmitting a disable for the identified dedicated circuit. In block 480, the AAC is activated. This may involve toggling as described with reference to FIGS. 3A-3C.

While various embodiments of the asymmetric aging control system have been described, it may be apparent to those of ordinary skill in the art that many more embodiments and implementations are possible that are within the scope of this system. Although certain aspects of the asymmetric aging control system may be described in relation to specific techniques or structures, the teachings and principles of the present system are not limited solely to such examples. All such modifications are intended to be included within the scope of this disclosure and the present asymmetric aging control system and protected by the following claim(s).

1. Asymmetrical aging control system associated with a dedicated circuit, comprising:
a first selection device adapted to be coupled to an input of the dedicated circuit;
a second selection device adapted to be coupled to a mode changing control input of the dedicated circuit;
a third selection device adapted to coupled to a clock input of the dedicated circuit;
control logic for receiving an input signal, transmitting a scan data signal to the first selection device, and transmitting mode control signal to the second selection device;
a register for transmitting random data for the second selection device; and
a counter for transmitting a first count signal to the second selection device and the register, and for transmitting a second count signal to the third selection device,
wherein the asymmetrical control logic uses a scan path associated with the dedicated circuit for varying data on at least one of the inputs of the dedicated circuit in a manner that minimizes power consumption of the associated dedicated circuit when the associated dedicated circuit is inactive.

2. The asymmetrical aging control system of claim 1, wherein an output device is coupled to an output of the dedicated circuit.

3. The asymmetrical aging control system of claim 2, wherein the output device further comprises a device selected from the group consisting of an AND gate and a state machine.

4. The asymmetrical aging control system of claim 1, wherein the register is a linear shift register.

5. The asymmetrical aging control system of claim 1, wherein the random data comprises pseudo random data.

6. The asymmetrical aging control system of claim 1, wherein the first count signal is transferred from a most significant bit of the counter.

7. The asymmetrical aging control system of claim 6, wherein the second count signal is transferred from a most significant bit minus 1 of the counter.

8. The asymmetrical aging control system of claim 1, wherein the first count signal is transferred from a most significant bit of the counter.

9. A computer readable medium with logical functions for controlling asymmetric aging of dedicated, comprising the steps consisting of:
enabling asymmetric aging control on all of the dedicated circuits;
disabling asymmetric aging control on active dedicated circuits;
monitoring a state associated with each dedicated circuit;
disabling asymmetric aging control for a first dedicated circuit associated with an activate request; and
deactivating a second dedicated circuit associated with a deactivate request.

10. The computer readable medium of claim 9 further comprising activating the first dedicated circuit in response to disabling asymmetric aging control for the first dedicated circuit.

11. The computer readable medium of claim 9 further comprising activating asymmetric aging control associated with the second dedicated circuit in response to deactivating the second dedicated circuit.

12. A router having a plurality of slots for expanded capacity, comprising:
an ASIC for facilitating data transmission to each of the slots and comprising a plurality of dedicated circuits associated with the slots; and
asymmetrical aging control circuit for either enabling or disabling a plurality of asymmetrical aging control logic, and each asymmetrical aging control logic is associated with each of the dedicated circuits,
wherein each of the asymmetrical aging control logic uses a scan path associated with the ASIC for varying data on its inputs in a manner that minimizes power consumption of the associated dedicated circuit while the associated dedicated circuit is inactive.
